(19) United States
(12) Patent Application Publication
(10) Pub. No.: US 2014/0370189 A1
(43) Pub. Date: Dec. 18, 2014

(54) Method for synthesis of Graphene Films With Large Area and High Throughput

(71) Applicants: Xuesong Li, Wappingers Falls, NY (US); Jia-Hung Wu, Wappingers Falls, NY (US); Hao Ning, Wappingers Falls, NY (US)

(72) Inventors: Xuesong Li, Wappingers Falls, NY (US); Jia-Hung Wu, Wappingers Falls, NY (US); Hao Ning, Wappingers Falls, NY (US)

(21) Appl. No.: 13/916,611

(22) Filed: Jun. 13, 2013

(51) Int. Cl. C23C 16/26; C23C 16/54

(52) U.S. Cl. CPC C23C 16/26; C23C 16/545
USPC 427/177; 427/178

(57) ABSTRACT

Improved methods for synthesizing large area thin films are disclosed, which result in films of enhanced width. The methods comprise providing a separator material which is rolled or wound up, along with the metallic foil substrate on which the thin film is to be deposited, to form a coiled composite which is then subjected to conventional chemical vapor deposition. Optionally, a winding tool may be used to aid in the rolling process. The methods enable a many-fold increase in the effective width of the substrate to be achieved.

This application is a Continuation-in-Part of application Ser. No. 13/655,588, filed Oct. 19, 2012.

### BACKGROUND OF THE INVENTION

1. Field of the Invention

The present invention relates broadly to the production of films via chemical vapor deposition, and in particular, to methods, for forming carbon films and other films using such deposition. More specifically, this invention relates to an improved method for processing a substrate prior to heating in a reactor chamber in order to form a large area thin film having an augmented width dimension.

2. Description of the Prior Art

Synthesis of graphene films on copper (Cu) foils by using chemical vapor deposition (CVD) technique is a promising way for graphene production (disclosed in US Patent Publication No. 2011/0091647), especially for large area graphene films. Since the graphene films are grown on the surface of copper foils, the size of graphene films is only determined by the size of copper foils, which is further restricted by the dimensions of the chamber of the CVD apparatus.

The chamber commonly used is a horizontally placed quartz tube heated by the tube furnace. To put the copper foils into the chamber, two dimensions should be considered, i.e., the length determined by the length of chamber and the width determined by the diameter of the chamber. Technically, there is almost no difficulty to make very long quartz tube or tube furnace. However, the difficulty to make large diameter quartz increases dramatically with the increase of diameter. In addition, the connections between the quartz tube and the metal parts also become worse with the increase of the quartz tube diameter because the manufactured errors such as size and roundness of the quartz tube increases as well.

Thus, with the limit of the quartz tube diameter, the way to load the copper foil determines the maxima width that can be achieved.

The straightforward way is to put a piece of flat copper foil. In this way, the maxima width is equal to the diameter of the chamber. Alternatively, the copper foil can be wrapped on a cylinder holder to achieve a maxima width of about three times of the chamber diameter, which is still not a great increase.

In this particular application, there is a need for large-area graphene film synthesis technique.

The present invention has arisen to mitigate and/or obviate the afore-described disadvantages.

### SUMMARY OF THE INVENTION

The primary object of the present invention is to provide a method for synthesizing graphene films of copper foils which is more flexible and is reused for more times.

Another object of the present invention is to provide a method for synthesizing graphene films of copper foils in which the surface of graphite foil is smooth and thus the smooth surface of substrate is kept

To obtain the above objectives, a method for synthesizing a thin film using chemical vapor deposition contains steps of:

heating a substantially flat substrate, forming a thin film on a surface of said substrate by exposing the substrate to chemical vapor deposition, and cooling the substrate to room temperature, the improvement comprising, prior to said heating step, providing a separator material, positioning said separator material adjacent to and in a substantially overlying relationship with said substrate to form a composite, and winding said composite so as to provide a coiled substrate;

wherein said separator material is comprised of a substance selected from the group consisting of fused quartz wool, ceramic insulation, a silica fabric, and a graphite foil.

### BRIEF DESCRIPTION OF THE DRAWINGS

These and other aspects, features, objects and advantages of the present invention will become more apparent to those skilled in the art from the following detailed description of the presently most preferred embodiments thereof (which are given for the purposes of disclosure), when read in conjunction with the accompanying drawings (which form a part of the specification, but which are not to be considered as limiting its scope), wherein:

FIG. 1 is a diagrammatic view depicting the process by which a thin film such as graphene is conventionally deposited on a surface of a substantially flat metallic foil substrate in the reactor chamber of a CVD device;

FIGS. 2-4 are enlarged schematic perspective views of a preferred embodiment of the present invention, showing a separator material overlying one surface of a metallic substrate, and also depicting the rolling or winding of the separator material together with the metallic substrate so as to form a cylindrical coiled composite, along with a tool used to effectuate the winding; and

FIG. 5 is a view substantially similar to that of FIG. 1, depicting a cylindrical coiled composite, formed in accordance with the present invention, positioned within the reactor chamber of a CVD device for deposition of a thin film onto the metallic foil substrate.

### DETAILED DESCRIPTION OF THE PREFERRED EMBODIMENTS

The preferred and other embodiments of the present invention will now be further described. Although the invention will be illustratively described hereinafter with reference to the formation of a large area graphene film on a copper foil substrate in a conventional CVD furnace, in the manner described generally in U.S. Patent Application Publication No. 2011/0091647, it should be understood that the invention is not limited to the specific case described, but extends also to the formation of boron-nitride and other large area thin films, utilizing other metallic foils (including nickel foils or aluminum foils) or other substrates, and using alternative vapor deposition processes such as PECVD or. ALD.

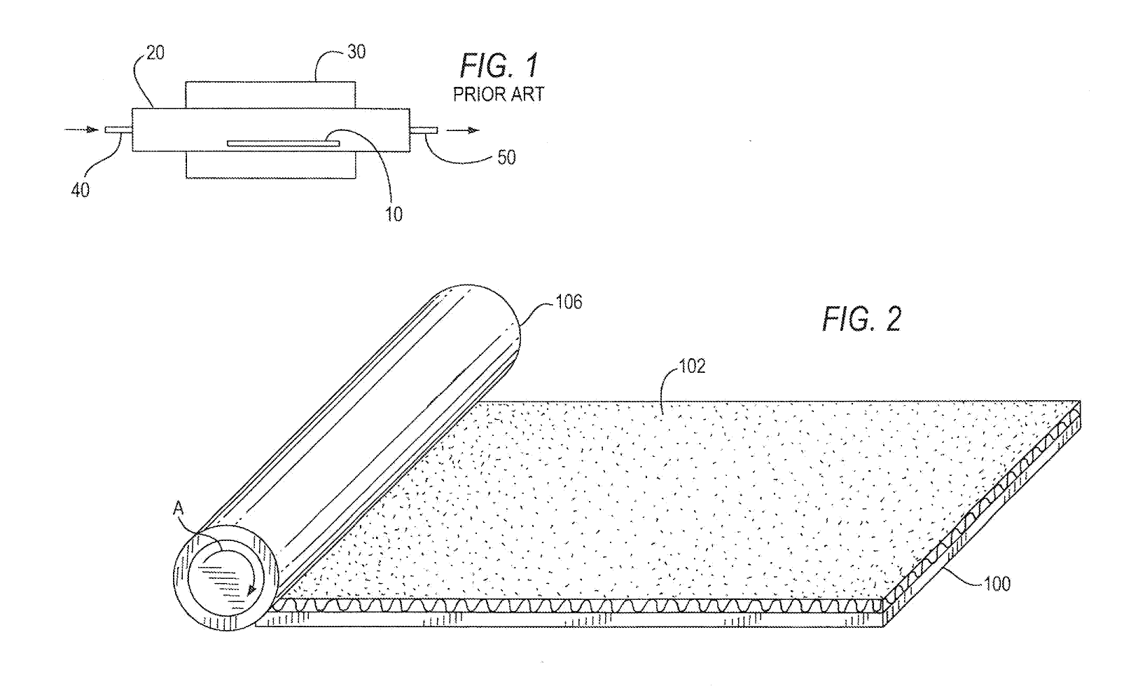

Referring first to FIG. 1, the conventional prior art process by which a thin film such as graphene may be deposited on a surface of a flat substrate 10 in the reactor chamber 20 of a CVD furnace 30 having a gas inlet 40 and a gas outlet 50, in the manner described generally in U.S. Patent Application Publication No. 2011/0091647, is depicted diagrammatically, but for ease of illustration, the substrate holder, heating elements and other components of a conventional CVD furnace have been omitted. It is to be understood that, except for the configuration of the substrate, the present invention utilizes the same conventional process.

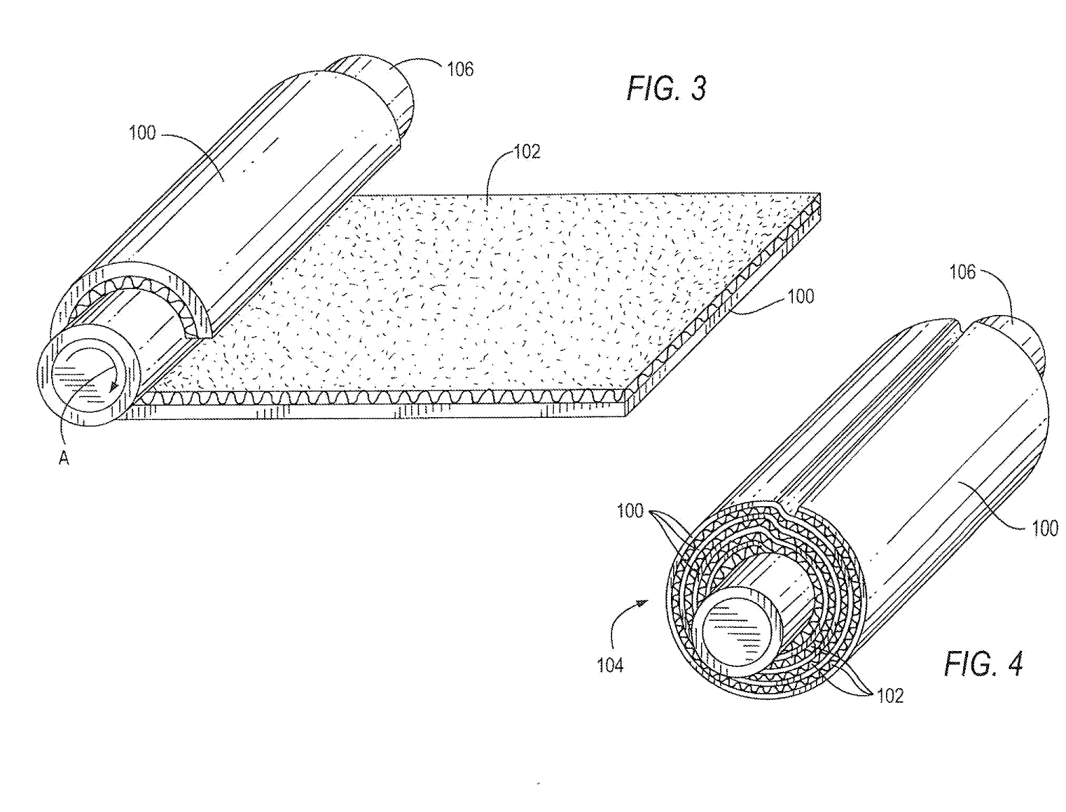

Referring now to FIGS. 2-4 in addition to the aforementioned FIG. 1, a preferred embodiment of the present invention will now be described. A copper foil substrate, having a thickness in the range of 10 μm-100 μm, and on the surfaces of which a large area thin film is to be formed, is generally designated 100. Initially, the copper foil substrate 100 is substantially flat, as can be seen in FIG. 2. A layer or mat of a separator material 102, which also is initially substantially flat, is positioned adjacent to and substantially overlying one surface of substrate 100, the length and width dimensions of separator material 102 being chosen so as to correspond substantially to that of substrate 100.

In general, separator material 102 should be fabricated of a substance which has a melting point greater than about 1,100 degrees Celsius, and which is also inert, i.e., which does not react with substrate 100, and does not interfere with or affect the growth of graphene on the surfaces of substrate 100.

Separator material 102 should be chosen to have a thickness in the range of from approximately 0.1 mm to approximately 2 mm, but within that range, it should be as thin as possible. Separator material 102 is composed most preferably of fused quartz wool or felt, which has a consistency similar to that of cotton, and which is provided in the form of a mat that is substantially flat and that can be cut to the proper size. An acceptable quartz wool product is available commercially from Technical Glass Products, Inc., located in Painseville Twp., Ohio, U.S.A., which markets this material under the product name Coarse 9 μm Nominal Wool (CQwool-1.1). Other quartz products in mat form which may be used as alternatives to fused quartz wool or felt include high purity quartz fabrics or cloths, which are available commercially, in a variety of different weights, sizes, thicknesses, weaves, and fiber configurations, from Fiber Materials, Inc., of Biddeford, Me., U.S.A.

Separator material 102 may alternatively be composed of preferred substances other than fused quartz, such as high-temperature textile fabrics, including silica fabrics. An acceptable amorphous silica fabric is commercially available from AVS Industries LLC of New Castle, Del., U.S.A., under the product name ULTRAFLX silica fabric, product numbers HT84CH or HT188CH. As an additional preferred alternative to quartz, separator material 102 may be composed of a thermal insulation such as the ultra high temperature flexible ceramic insulation which is commercially available in roll form, in a variety of lengths, thicknesses and densities, under product numbers which commence with the designation 93315K, from McMaster-Carr Supply Company, based in Elmhurst, Ill., U.S.A.

After separator material 102 is positioned as shown in FIG. 2, it is rolled up or wound up together with substrate 100, as shown in FIGS. 3-4, so as to form a substantially cylindrical coiled composite 104, in which a layer of separator material 102 is interleaved between adjacent layers of substrate 100. Although the cylindrical composite 104 can be formed by hand, without the use of an aid, optionally the winding tool 106 may be used as to aid in the rolling or winding process. Winding tool 106 is preferably substantially cylindrical in shape, and can take the form of either a solid rod or a hollow tube, although other, non-cylindrical shapes may alternatively be used effectively.

In order to facilitate grasping winding tool 106 for rotation, its length should generally be chosen so as to be approximately 10 cm greater than the corresponding dimension of separator material 102 and/or substrate 100, thereby enabling winding tool 106 to be positioned such that a portion extends out and away from separator material 102 by approximately 5 cm on either side. Then, separator material 102 may be wound up, along with substrate 100, by grasping the extended portions of winding tool 106 on either side, and by turning or rotating it (e.g., by spinning, winding or twirling), in the direction indicated by arrows A in FIGS. 2-3, either manually or with the aid of a mechanical spinning device, until a substantially cylindrical coiled composite body 104 is formed, with winding tool 106 positioned at its core.

Winding tool 106 is preferably comprised of fused quartz, and hollow fused quartz tubes, as well as solid fused quartz rods, which are acceptable for use as winding tool 106 are available commercially from Technical Glass Products, Inc., located in Painseville Twp., Ohio, U.S.A., which markets a wide variety of such items. Most preferably, a hollow fused quartz tube having an inner diameter of 8 mm and an outer diameter of 10 mm is used when the reactor chamber or cavity of the CVD apparatus that is to be used has a 2-inch diameter, while a hollow fused quartz tube having an inner diameter of 46 mm and an outer diameter of 50 mm is used when the reactor chamber has a 5-inch diameter, although hollow fused quartz tubes having inner diameters between 8 mm and 46 mm and outer diameters between 10 mm and 50 mm may be used as well, depending on the size of the reactor chamber. If a solid fused quartz rod is to be used instead of a hollow tube, then most preferably a solid fused quartz rod having a 10 mm diameter is used when the reactor chamber has a 2-inch diameter, while a solid fused quartz rod having a 40 mm diameter is used when the reactor chamber has a 5-inch diameter, although solid fused quartz rods having diameters between 10 mm and 40 mm may be used as well, depending on the size of the reactor chamber.

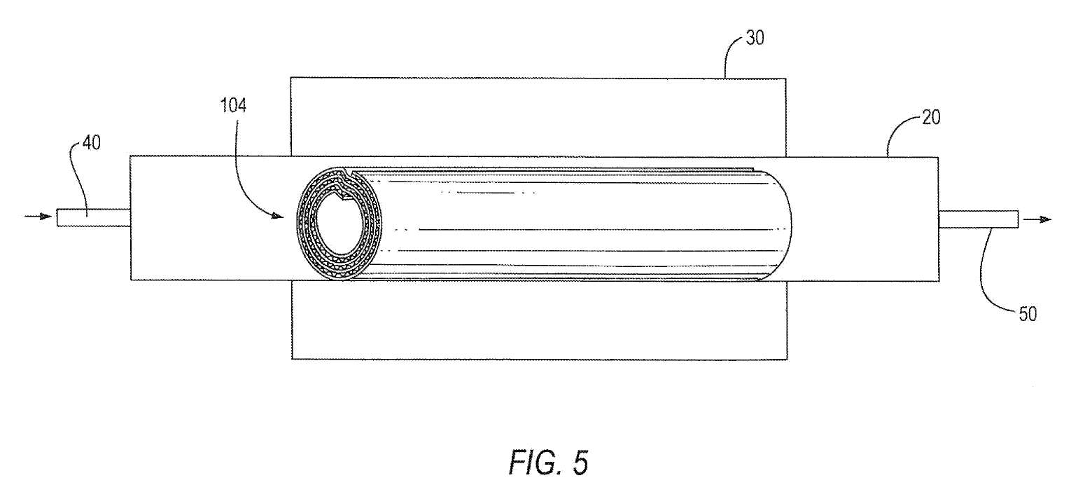

Referring now to FIG. 5 in addition to the aforementioned FIGS. 1-4, following the rolling or coiling step, the winding tool 106 (if any) is removed from the core of cylindrical coiled composite 104 by sliding it laterally (the removal step is not shown in the drawings), and coiled composite 104 may then be placed into the reactor chamber 20 of a CVD furnace 30 so as to allow a graphene coating (not shown in the drawings) to be deposited onto the surfaces of substrate 100 using a CVD process.

Following the deposition of the graphene coating, removal of the cylindrical coiled composite 104 from the CVD furnace, and cooling, the coiled composite may be unrolled by hand, and separator material 102 may be removed (these steps are not shown in the drawings). Depending upon the durability of separator material 102 and the degree of its contamination from the metallic substrate, separator material 102 may be re-used, perhaps as many as 20-30 times, following which it should be discarded. After separator material 102 is removed, the graphene coating on substrate 100 may be used, either directly with substrate 100 still attached, or it may first be separated or transferred from the surfaces of substrate 100 in a known manner (for example, a salt solution which is an oxidizing agent may be used to exfoliate the graphene coating from the substrate), following which the separated graphene layers may be utilized in a graphene application or otherwise further processed for ultimate use.

The enhanced width of the thin film that can be synthesized using the process of the present invention may be calculated according to the following equation:

$$W = \frac{π ( {D}^{2} - {d}^{2} )}{4 ( t + {t}^{′} )}$$

wherein:

D=the inner diameter of the CVD reactor chamber;

d=the outer diameter of winding tool 106, if used (if not used, then d=0);

t=the thickness of separator material 102; and

t′=the thickness of substrate 100.

Thus, as an example, if the inner diameter of the reactor chamber or cavity of the CVD apparatus is 46 mm, and if the outer diameter of winding tool 106 is 10 mm, the thickness of separator material 102 is 2 mm, and the thickness of substrate 100 is 0.025 mm, then a thin film of having a width of 782 mm may be produced, which is approximately 16 times wider than the diameter of the reactor chamber of the CVD apparatus. As a further example, if the inner diameter of the reactor chamber is 125 mm, and the values for the other three variables remain the same, then a thin film of having a width of 6,021 mm may be produced, which is approximately 48 times wider than the diameter of the reactor chamber. These examples illustrate that the invention provides a facile process by which thin films of enhanced width, as compared with the width of the reactor chamber itself, may be formed.

Also, separator material 102 may be composed of a graphite foil, and a graphite foil is putted on the substrate 100; then the graphite foil and the substrate 100 are rolled up by applying the winding tool 106, thereafter the winding tool 106 is placed into a reactor so as to grow the graphene on the substrate 100; finally the graphite foil and the substrate 100 are unrolled and removed after growing the graphene.

Thereby, the graphite foil is used as a buffer layer to roll up the copper foil so as to grow graphene on an area much larger than the CVD chamber dimensions.

It is to be noted that a width limit can be calculated via the following equation:

$$W = \frac{π ( {D}^{2} - {d}^{2} )}{4 ( t + {t}^{′} )}$$

wherein

t=thickness of the separator material 102 (i.e., the graphite foil)

t′=thickness of the substrate 100 (i.e., the metal foil)

D=inner diameter of the CVD reactor chamber

d=the outer diameter of winding tool 106

Also, in another embodiment of the present invention, t=0.125 mm, t′=0.025 mm, D=46 mm, d=10 mm, then W=10555 mm, about 230 times larger than the CVD reactor chamber.

In the other embodiment of the present invention, t=0.125 mm, t′=0.025 mm, D=125 mm, d=10 mm, then W=81289 mm, about 650 times larger than the CVD reactor chamber.

While there has been described what are at present considered to be the preferred embodiments of the present invention, it will be apparent to those skilled in the art that the embodiments described herein are by way of illustration and not of limitation. Various modifications of the disclosed embodiments, as well as alternative embodiments of the invention, will become apparent to persons skilled in the art upon reference to the description of the invention. Therefore, it is to be understood that various changes and modifications may be made in the embodiments disclosed herein without departing from the true spirit and scope of the present invention, as set forth in the appended claims, and it is contemplated that the appended claims will cover any such modifications or embodiments.

What is claimed is:

1. In a method for synthesizing a thin film using chemical vapor deposition, said method comprising the steps of
heating a substantially flat substrate, forming a thin film on a surface of said substrate by exposing the substrate to chemical vapor deposition, and cooling the substrate to room temperature, the improvement comprising, prior to said heating step, providing a separator material, positioning said separator material adjacent to and in a substantially overlying relationship with said substrate to form a composite, and winding said composite so as to provide a coiled substrate;
wherein said separator material is comprised of a substance selected from the group consisting of fused quartz wool, ceramic insulation, a silica fabric, and a graphite foil.

2. The method of claim 1 wherein said separator material is provided in the form of a substantially flat mat, and wherein the thickness of said mat is in the range of from approximately 0.1 mm to approximately 2 mm.

3. The method of claim 2 wherein said separator material is comprised of fused quartz wool.

4. The method of claim 1 wherein the winding step is accomplished with the aid of a winding tool.

5. The method of claim 4 wherein said winding tool is comprised of fused quartz.

6. The method of claim 5 wherein said winding tool is substantially cylindrical in shape, and wherein the form of said winding tool is selected from the group consisting of a hollow tube and a solid rod.

7. The method of claim 1 wherein the thin film is selected from the group consisting of graphene and boron nitride.

8. The method of claim 7 wherein the substrate is comprised of a metallic foil.

9. The method of claim 8 wherein the thin film is graphene, and wherein said metallic foil is comprised of copper.

10. The method of claim 1 wherein said separator material is comprised of a graphite foil, and the graphite foil is putted on the substrate, the graphite foil and the substrate are rolled up by applying the winding tool, the winding tool is placed into a reactor so as to grow the graphene on the substrate, the graphite foil and the substrate are unrolled and removed after growing the graphene.
